(19) United States
(12) Patent Application Publication
(10) Pub. No.: US 2007/0103988 A1
(43) Pub. Date: May 10, 2007

(54) Circuit arrangement and method for controlling an inductive load

(76) Inventors: Bernhard Bauer, Pentling (DE); Mauricio Hernandez-Distancia, Neutraubling (DE); Milan Krstev, Regensburg (DE)

Correspondence Address: LERNER GREENBERG STEMER LLP, P O BOX 2480, HOLLYWOOD, FL, 33022-2480, US

(21) Appl. No.: 10/581,473

(22) PCT Filed: Nov. 29, 2004
(86) PCT No.: PCT/EP04/53147

§ 371 Date: Jun. 1, 2006

(30) Foreign Application Priority Data
Dec. 1, 2003 (DE) 10356089.0

(51) Int. Cl. G11C 11/34

(52) U.S. Cl. 365/185.22

(57) ABSTRACT

A circuit configuration controls an inductive consumer, especially protecting the consumer from being accidentally turned on. The circuit configuration contains a free-wheeling circuit for reducing energy stored in the consumer. In order to prevent the consumer from being accidentally turned on when a grounding wire between an energy store and the circuit configuration is interrupted, the free-wheeling circuit is interrupted after a given period of time once the consumer has been turned off such that the consumer is prevented from being charged by a current flowing from the positive pole of the energy store via the electronics of the circuit configuration and the free-wheeling circuit.

The invention relates to a circuit arrangement and a method for controlling an inductive load, in particular to a protective circuit that will prevent an actuator from being activated in a fault situation.

Electrical loads and actuators are switched on and off by means of electronic control devices. In automotive engineering, electrical loads such as, for example, the excitation coil of a fuel injection valve or of a starting motor are usually actuated by means of a switch element connected in series with the load. Said switch element is often part of a control device connected at the input side to the two poles of a supply voltage source. Frequently only one potential of the supply voltage source is ducted to the load via the control device. In automotive engineering, the second potential is usually ducted to the load via the bodywork, which is applied to frame potential.

If the ground lead leading from the negative terminal of the supply voltage source to the control device is interrupted, it cannot be precluded in the case of certain loads that the load will also be supplied with power when not desired.

There may be undesired load powering in the event of a ground interruption especially in the case of inductive loads which, after being switched off, have to discharge the energy stored in them via a freewheeling circuit.

Two cases can be distinguished here: On the one hand, when the switch element has been switched on the load will continue to be powered by a current flowing from the positive potential of the supply voltage source to the external ground terminal via the switch element and load; on the other hand, when the switch element has been switched off the internal ground of the control device will be “pulled” in the direction of the positive potential of the supply voltage source depending on the state of the control electronics and of the electrical load. This will result in a flow of current from the positive pole of the supply voltage source via the freewheeling circuit and to external ground. What is problematic therein is the risk that the electrical load can be undesirably switched on owing to said flow of current. Taking the starter relay as an instance, there will in this case be an undesired start operation which it is imperative to prevent for safety reasons.

This problem can be resolved in a known manner by providing a safety-critical load of said kind with a second ground lead so that the load is electrically connected directly to the ground of the control device. With a plurality of loads, however, this solution has proved to be complex and very expensive.

The object of the invention is to provide a circuit arrangement and a method for controlling an inductive load that will also prevent the inductive load from being switched on in the event of a fault.

Said object is achieved by means of a circuit arrangement having the features of claim 1 and a method having features of claim 5.

The circuit arrangement has a first and a second input as well as an output. The first input is electrically connected to a first potential of a supply voltage source and the second input is electrically connected to a second potential of the supply voltage source. The load is connected on the one hand to the output and on the other hand to the second potential of the supply voltage source.

In the present case there is thus no direct connection between the second potential ducted to the circuit arrangement and the load. The circuit arrangement furthermore has a first switch, which can be controlled by a signal, for switching the load connected on the one hand to the first input and on the other hand to the output of the circuit arrangement on and off. When the switch has been closed, in standard operation a current flows from the first potential of the supply voltage source to the second potential of the supply voltage source via the controllable switch and the load.

The circuit arrangement furthermore has a freewheeling circuit which is connected on the one hand to the second input and on the other hand to the output of the circuit arrangement and has a second switch. The energy stored in the load will discharge via said freewheeling circuit if the load is switched off by opening the first switch. The second switch is closed for this purpose.

A monitoring unit monitors a potential in the freewheeling circuit and opens or closes the second switch as a function of said potential. The second switch is therein preferably controlled in such a way that the freewheeling circuit is activated during the load's switch-off phase and then deactivated when the freewheeling circuit is not required.

Advantageous developments of the invention are described in the subclaims.

The monitoring unit opens or closes the second switch when a predefined voltage threshold is undershot or exceeded. What is achieved thereby is that the load will not be inadvertently switched on in the event of a fault, which is to say when ground is lost in the circuit arrangement.

The monitoring unit additionally has a delay element that will open the second switch with a predefined delay if the predefined voltage threshold is undershot or exceeded. It is thereby ensured that the energy stored in the inductive load will be discharged during this time via the freewheeling circuit. The freewheeling circuit will preferably remain interrupted after this discharge operation owing to the opened second switch and a flow of current via said freewheeling circuit toward the load will be prevented.

Advantageous developments of the invention are described in the dependent claims.

In order to preclude the load's being switched on again in a fault situation through closing of the first switch, the circuit arrangement preferably has a linking unit that will only allow the load to be switched on if unintentional switching on in a fault situation has been precluded, preferably when the first switch has first received a switch-off and then a switch-on signal and/or the monitoring unit has closed the second switch.

The invention is explained in more detail below with reference to the description and the figures relating to a preferred exemplary embodiment.

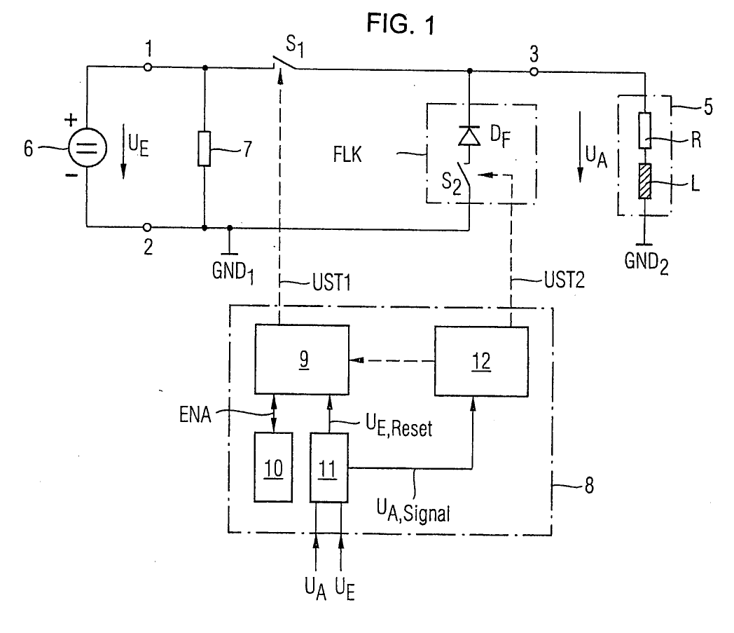

FIG. 1 shows an exemplary embodiment of an inventive circuit arrangement,

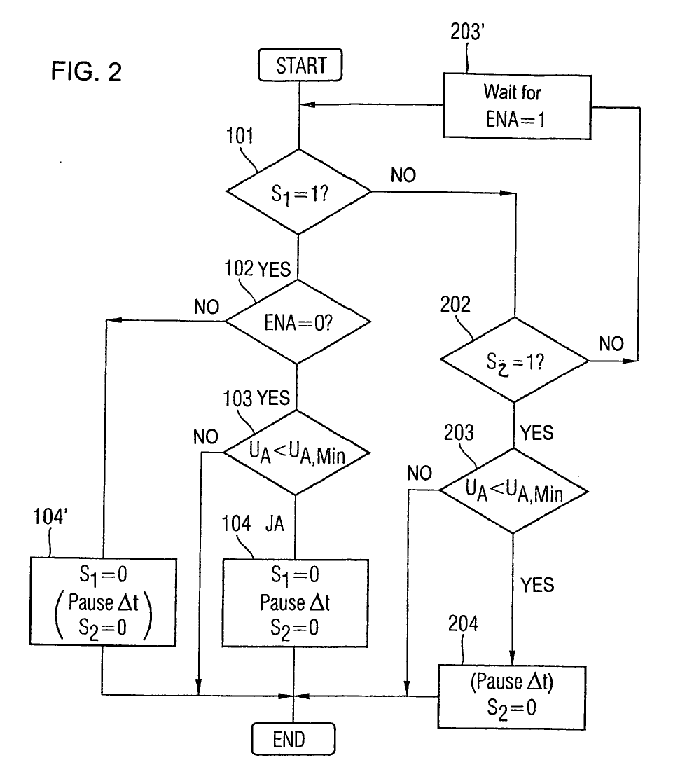

FIG. 2 is a flowchart showing the steps in an exemplary embodiment of the inventive method, and

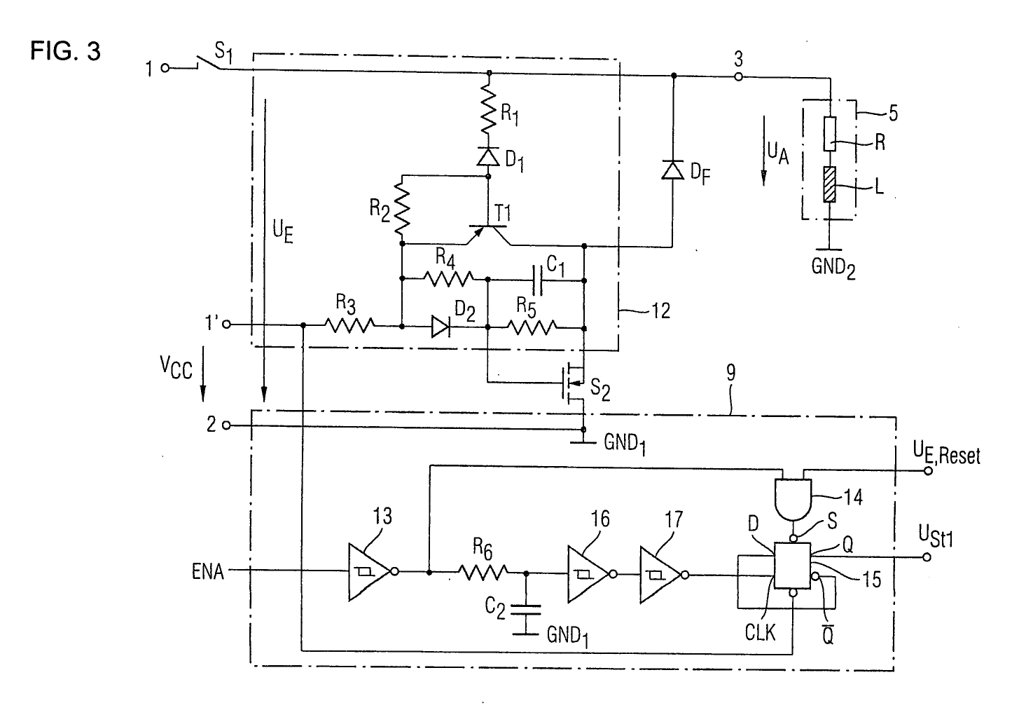

FIG. 3 shows an exemplary embodiment of a delay element and linking unit.

FIG. 1 shows an exemplary embodiment of a circuit arrangement for controlling an inductive load 5. The load 5 is here described in equivalent terms in the form of an inductor L and a resistor R connected in series.

$$E = \frac{1}{2} L \cdot {I}^{2}$$

The circuit arrangement has a first input 1 and a second input 2 which are each electrically connected to a potential of a supply voltage source, in this case an accumulator 6. The first terminal 1 is here electrically connected to the positive pole + of the accumulator 6 and the second input 2 is electrically connected to the negative pole − of the accumulator 6. The electronic components arranged in the control device between the inputs 1 and 2 are shown here as the equivalent resistance 7. The equivalent resistance 7 corresponds to a parallel connection of all components directly or indirectly supplied by the accumulator 6.

The circuit arrangement furthermore has a first switch S1 which is electrically connected on the one hand to the first input 1 and on the other hand to an output 3. The load 5 is electrically connected on the one hand to the output 3 and on the other hand to ground GND₂.

In the exemplary embodiment shown here there is no direct connection between the internal ground of the circuit arrangement GND₁ and the ground GND₂ of the load 5. The bodywork of the vehicle is usually employed as the ground connection in the field of automotive engineering.

A freewheeling circuit FLK has been arranged between the second input 2 and the output 3 in order to discharge the energy E stored in the inductor L when the load has been switched off (achieved here by opening the switch S1), and hence to deactivate the load 5. Said freewheeling circuit FLK here has a second switch S2 and a diode D_{F} connected in series. If the second switch S2 is closed, a current I will flow from the load 5 via the diode D_{F} and the switch S2 for a limited period t_{entlade} after the first switch S₁ has been opened.

The discharge time t_{entlade} depends on the energy E stored in the inductor L of the load 5:
E=½L·I²

$${I}_{0} = \frac{{U}_{A}}{R} .$$

When the inductor L is charging, the current intensity I initially increases linearly and approaches the constant terminal value I₀:
I₀=U_{A}/R.

The discharge time t_{entlade} of the coil L can be obtained from the equation

$$I = {I}_{0} \cdot {ⅇ}^{- \frac{R}{L} t} .$$

The first switch S1 embodied here as what is termed a “high-side” switch can also be embodied as a “low-side” switch. Only the connection of the terminals 1 and 2 to the poles of the accumulator 6 and the direction of flow of the freewheeling diode D_{F} change as a result. The load 5 would then be electrically connected with its terminal facing away from the output 3 to the positive potential + of the accumulator 6.

The first switch S1 and the second switch S2 are embodied as controllable electrical switches, for example as power MOS Field Effect Transistors (MOSFETs) or Insulated Gate Bipolar Transistors (IGBTs). The control terminals of said switches S1, S2 are controlled by a control circuit 8, with the first switch S1 being electrically connected via a first control line UST1 and the second switch S2 via a second control line UST2 to the control circuit 8.

The control circuit 8 has a linking unit 9, a microcontroller 10, a supply voltage monitor 11, and a delay element 12. The supply voltage monitor 11 has two inputs, namely a first input UE that is electrically connected to the first input 1 of the circuit arrangement and a second input UA that is electrically connected to the output 3 of the circuit arrangement.

The supply voltage monitor 11 furthermore has two outputs. One of said outputs, U_{E, Reset}, is electrically connected to the linking unit 9 and the other output, U_{A, signal}, is electrically connected to the delay element 12. The microcontroller 10 has at least one output ENA that is connected to the linking unit 9. The linking unit 9 is furthermore connected to the control line UST1 of the control circuit 8. The delay element 12 is connected to the second control line UST2 of the control circuit 8.

Provided there is no fault situation and the first switch S1 is closed, a voltage UA corresponding approximately to the input voltage U_{E} will drop via the load 5.

FIG. 2 is a flowchart with the aid of which the method steps required to operate the load 5 are explained in more detail.

The start of flow is identified by the term “START”. An inquiry is first made here to determine whether the first switch S1 has been closed (step 101). On the basis of this distinction it is possible to distinguish between two possible fault instances, namely the loss of ground when the load 5 has been switched on and the loss of ground in the circuit arrangement when the load 5 has been switched off.

In the first instance, with the first switch S1 closed, a check is made in step 102 to determine whether there is a switch-off signal from the microprocessor 10. In that case the switch-on signal ENA would have been set from the status “0” to the status “1” and, consequently, the first switch S1 will then be opened (ENA=“1” here corresponds to a Low level). If demanded by the safety requirements placed on the load 5, the second switch S2 will also be opened after a predefined period Δt during which the energy stored in the inductor L will discharge via the freewheeling circuit FLK. Inadvertent switching on of the load 5 in the event of an interruption to the connecting lead between the negative terminal − of the accumulator 6 and the input 2 would thus be precluded even with the load 5 then being switched off (step 104′). A branch is made to the end of the flowchart after step 104′.

The predefined period Δt has here been selected such that the inductor L will have very largely discharged on expiration of said period Δt.

The period Δt can be selected within the following range:
5τ≦Δt≦10τ, where τ=L/R.

If the period Δt is selected as being too long, switching on could in a fault situation take place again during said period. The period Δt must therefore be dimensioned as required for discharging the energy in the load 5.

If a switch-on signal ENA of the microcontroller 10 remains present in step 102, a branch will be made to step 103 where a check will be carried out on the output voltage U_{A}. In standard operation the output voltage U_{A} corresponds approximately to the input voltage U_{E}.

With the first switch S1 open and/or if there is loss of ground, which is to say, in this case, an interrupted lead between the negative pole − of the accumulator 6 and the second input 2, the output voltage U_{A} will correspond approximately to the conducting state voltage of the freewheeling diode D_{F}. Said conducting state voltage depends on the type of freewheeling diode D_{F} and in the exemplary embodiment described here is approximately −0.7 volt. Depending on said conducting state voltage of the diode D, a voltage threshold U_{A, MIN} is defined below which a current will flow in the freewheeling circuit FLK.

If the output voltage U_{A} is above said predefined threshold U_{A, MIN} then a fault situation can be precluded and a branch will be made to the end of the flowchart.

If, however, the output voltage U_{A} is below the predefined threshold U_{A, MIN}, then if the first switch S1 is closed a “detached” ground connection in the circuit arrangement must be inferred and a branch will be made to step 104. There, the first switch S1 will first be opened, then, after the predefined period Δt, which, as already described, depends on the discharge time t_{entlade} of the inductor L, the second switch S2 will be opened and a flow of current from the accumulator 6 via the input 1, the equivalent resistance 7, the second switch S2, the diode D, and the load 5 hence interrupted. Unintentional switching on of the load 5 will thus be precluded when the second switch S2 has been opened and a branch will be made to the end of the flowchart.

Alternatively an error flag can additionally be set here via which the interruption in the ground lead is reported to a control device.

If the first switch S1 is not closed in step 101 a branch will be made to step 202, in which a check is carried out to determine whether the second switch S2 is closed. If switch S2 is closed, another check is carried out in step 203 to determine whether the output voltage U_{A} is below the predefined threshold U_{A, MIN}. If it is, a branch will be made to step 204 and the switch S2 opened, following which a branch will be made to the end of the flowchart. If it is not, or if the output voltage UA is zero, a branch will be made directly to the end of the flowchart. It is alternatively also possible not to open the second switch S2 until after the predefined period Δt.

If the switch S2 is open in step 202 (S2=0) a branch will be made to step 203′, where a switch-on-again signal of the microcontroller 10 will be awaited. Said switch-on-again signal can be, for example, a status change of the switch-on signal ENA from status 0 to status 1. This will prevent the load from being switched on again inadvertently after a loss of ground.

The execution of the method described here can be launched, for example, as a function of an operating status of the load 5 or of the microcontroller 10, or by means of an external control signal.

FIG. 3 shows an exemplary embodiment of the delay element 12 and of the linking unit 9.

If the switch S1 is closed, a voltage U_{A} corresponding approximately to the input voltage U_{E} will be applied to the load 5. The delay element 12 has a power supply input 1′ which is independent of the switch element S1 and serves to supply the circuit arrangement with power. Arranged between the output 3 and said input 1′ is a series circuit consisting of a first resistor R1, a diode D1 switched in the non-conducting direction, a second resistor R2, and a third resistor R3. The switch S2 is here implemented as an n-channel MOSFET, with its drain terminal being connected to the second input 2 and its source terminal being connected via the freewheeling diode D_{F} switched in the direction of flow to the output 3. The gate terminal is connected to the center tap of a series circuit consisting of a fourth resistor R4 and a first capacitor C1, with the second terminal of the fourth resistor R4 being connected to the center tap between the second resistor R2 and the third resistor R3. The second terminal of the capacitor C1 is connected to the source terminal of the switch S2.

The center tap between a second diode D2 and a fifth resistor R5 is likewise connected to the gate terminal of the switch S2, with the second diode D2 being arranged with its direction of flow in the direction of the gate terminal of the switch S2 parallel to the fourth resistor R4 and the fifth resistor R5 being arranged parallel to the first capacitor C1.

The base-emitter path of a transistor T1 is arranged parallel to the second resistor R2. In the exemplary embodiment shown here the transistor T1 is a pnp transistor. The base terminal of the transistor T1 is connected to the tap between the second resistor R2 and the diode D1. The emitter terminal is connected to the tap between second and third resistor R2 and R3. The collector terminal of the transistor T1 is connected to the output 3 facing away from the terminal of the freewheeling diode D_{F}.

When the switch S1 is closed the transistor T1 is non-conducting and the capacitor C1 is charged via the third resistor R3 and the second diode D2 up to the supply voltage VCC being applied at the input 1′. The switch S2 is closed as a result and the freewheeling circuit FLK thereby activated. The circuit arrangement is dimensioned in such a way that the switch S2 will be closed before a larger amount of energy has been stored in the inductor L of the load 5.

If the switch S1 is then opened, a current will flow through the freewheeling circuit FLK formed from the switch S2 and the freewheeling diode D_{F} owing to the energy stored in the inductor L of the load 5. An output voltage U_{A} of approximately 0.7 volt will then drop via the load 5. This corresponds to the conducting state voltage of the freewheeling diode D_{F}. The transistor T1 will be closed owing to said voltage and the capacitor C1 will discharge via the resistor R4. The transistor T2 will be turned off when the capacitor C1 has discharged. The time Δt between opening of the switch S1 and opening of the switch S2 is selected such that the energy stored in the inductor L will have very largely discharged by the time the switch S2 is opened.

With switch S1 open and switch S2 open, the connection between the negative pole − of the accumulator and the second input 2 will then be interrupted so that no current can flow to the load 5 via the freewheeling circuit FLK.

The linking unit 9 is embodied for the following input variables: A switch-on signal of the microcontroller 10 (ENA=0) corresponds to a Low level at the input ENA; a switch-off signal (ENA=1) corresponds to a High level at the input ENA. The supply voltage monitor 11 supplies a High-level signal at the input U_{E, Reset} as long as the supply voltage VCC is of sufficient strength. A Low level at the input U_{E, Reset} stands for a supply voltage VCC that is below a predefined voltage threshold.

The signal ENA arriving from the microcontroller 10 is inverted in a first inverter 13 and routed to an AND gate 14. The second input of the AND gate 14 is connected to the output U_{E, Reset} of the supply voltage monitor 11. The output of the AND gate 14 will continue to have a High level as long as both input signals, which is to say the inverted input signal ENA and the signal of the supply voltage monitor U_{E, Reset}, have a High level.

The voltage levels at the outputs are assigned to the “Low” and “High” levels as follows:

Low level corresponds to: 0 V<U<0.4 V

High level corresponds to: 3.7 V<U<4.5 V

(HCMOS chip 74HC with a supply voltage of VCC=4.5 V)

The output signal of the AND gate 14 is routed to the set input S of a D flip-flop 15. The output signal of the first inverter 13 is routed to the clock input CLK of the D flip-flop 15 via a low-pass filter consisting of a resistor R6 and a capacitor C2 and two further inverters 16 and 17. The inverted output Q̅0 is fed back to the D input D of the D flip-flop 15. The output Q of the D flip-flop 15 is here connected to the control line U_{ST1}. If, owing to an undervoltage, a Low level is now being applied at the input U_{E, Reset} and if a switch-on request of the microcontroller 10 has simultaneously been set (Low level at the input ENA), then there will be a Low level at the set input S of the D flip-flop 15. There will as a result be a High level at the output Q of the D flip-flop 15 and the first switch S1 will hence be opened.

If the microcontroller 10 issues a switch-off instruction (High level at the input ENA), then the switch S1 will likewise be opened via the set input S. A High level at the input ENA will result in a Low level at the input of the AND gate 14. This means to say there will be a Low level at the output of the AND gate independently of the signal U_{E, Reset}. This will result in a High level at the output Q of the D flip-flop 15, as a consequence of which the switch S1 will remain open.

The first switch S will be closed when there is a negative edge at the input ENA, which is to say when there is a change from a High to a Low level or when there is a positive edge at the clock input CLK of the D flip-flop. Using the low-pass filter R6, C2 achieves a signal delay that has been set in such a way through appropriate choice of the sixth resistor R6 and of the capacitor C2 that the High level will in any event be applied at the set input S of the D flip-flop 15 before the positive edge of the signal arrives at the clock input CLK of the D flip-flop 15.

Arranged in the circuit between the resistor R6 and the clock input CLK of the D flip-flop 15 are two inverters 16, 17 in the form of a Schmitt trigger inverter by which the edge steepness at the clock input CLK is improved. A non-inverting Schmitt trigger gate can alternatively also be arranged in the circuit instead of the two inverters.

In a fault situation when the ground terminal at the control device has been interrupted and a switch-on signal ENA (Low level) is simultaneously being applied at the output of the microcontroller 10, the first switch S will be opened, as already described, via the set input S of the D flip-flop 15. When the load 5 has been switched off the supply voltage VCC will, however, rise again, as has also already been described. In order then to prevent the load 5 from being switched on again after the supply voltage monitor 11 again indicates by way of a High level that there is sufficient supply voltage VCC, it is ensured that switching on again of said load 5 by the microcontroller 10 will only be possible if said microcontroller 10 provides a switch-off signal (High level) at the output ENA then a switch-on signal (Low level).

1-4. (canceled)

5. A circuit configuration for controlling an inductive load, comprising:
a supply voltage source having a first potential terminal and a second potential terminal;
a first input connected to said first potential terminal;
a second input connected to said second potential terminal;
an output for connecting to the inductive load, the inductive load being further connected to said second potential terminal of said supply voltage source;
a first switch connected between said first input and said output, said first switch receiving and controlled by a first control signal for switching the inductive load on and off;
a freewheeling circuit connected between said second input and said output, said freewheeling circuit having a second switch; and
a monitoring unit monitoring a potential in said freewheeling circuit and closes and/or opens said second switch via a second control signal in dependence on the potential, said monitoring unit having a delay element for opening said second switch after a predefined period when a predefined voltage threshold has been undershot or exceeded, with a result that after the predefined period energy stored in the inductive load will have discharged via said freewheeling circuit.

6. The circuit configuration according to claim 5, wherein said monitoring unit has a linking unit with two inputs and one output outputting the first control signal, the first control signal being dependent on a level and a time curve of signals at said two inputs of said linking unit.

7. The circuit configuration according to claim 5, wherein the circuit configuration is a protective circuit providing safe operation of the inductive load.

8. A method for controlling an electrical load, which comprises the steps of:
checking an actuation status of a first switch;
comparing a first voltage with a predefined voltage threshold resulting in a comparison result;
determining a fault situation in dependence on the comparison result and the actuation status of the first switch; and
operating a second switch in dependence on the comparison result and/or the actuation status of the first switch, an operation of the second switch being delayed by a predefined period, resulting in that after the predefined period lapses energy stored in the electrical load will have discharged via a freewheeling circuit.

9. The method according to claim 8, which further comprises closing the first switch with a switch-on-again signal after a fault situation.
